(19) United States
(12) Patent Application Publication
(10) Pub. No.: US 2011/0175628 A1
(43) Pub. Date: Jul. 21, 2011

(54) TRIPLE-GATE OR MULTI-GATE COMPONENT BASED ON THE TUNNELING EFFECT

(76) Inventor: Hermann Kohlstedt, Preetz (DE)

(21) Appl. No.: 12/737,227

(22) PCT Filed: Jun. 19, 2009
(86) PCT No.: PCT/DE2009/000844

§ 371 Date: Feb. 8, 2011

(30) Foreign Application Priority Data
Jul. 5, 2008 (DE) 10 2008 031 819.1

(51) Int. Cl. G01R 27/28; H01L 39/22

(52) U.S. Cl. 324/649; 257/36; 505/220; 257/E39.016

(57) ABSTRACT

Disclosed is a triple-gate or multi-gate component based on the quantum mechanical tunnel effect. The component comprises at least two tunneling electrodes on a substrate that are separated by a gap through which electrons can tunnel. The component comprises an arrangement for applying an electric field to the gap, which is such that the path of an electron tunneling between the tunneling electrodes is elongated as a result of the deflection caused by this field. In general, an arrangement can also be provided for applying an electric field to the gap, this electric field having a field component that is perpendicular to the direction of the tunnel current between the tunneling electrodes and is parallel to the substrate. Since the tunnel current between the tunneling electrodes exponentially depends on the distance traveled by the electrons in the gap, such an electric field has a penetration effect on the tunneling probability and thus on the tunnel current to be controlled. Such a component can act as a very fast switching transistor having high amplification and does not have to be semiconducting.

The invention relates to a triple-gate or multi-gate component based on the quantum mechanical tunnel effect.

### STATE OF THE ART

A transistor is a component, the electric resistance of which can be varied by a control current or by a control voltage. In essence, two different technical concepts exist: the bipolar junction transistor and the field-effect transistor. Both types of transistors have in common that they are designed as semiconductors. The bipolar junction transistor comprises a sequence of alternately n-doped and p-doped semiconductor regions (NPN or PNP transistors). A control current varies the space charge density at the n-p or p-n junctions and thereby varies the conductivity of the transistor. A field-effect transistor is composed of a semiconductor having only one doping type. An electric field supplied by a gate electrode is used to vary the space charge density in this semiconductor, so as to modulate the conductivity of a channel through this semiconductor.

The switching speed of transistors is reaching its limits, since scaling at nanometer levels is becoming increasingly difficult. Further miniaturization is also hindered by ever-more complex manufacturing processes, and because ever more power dissipation in the form of heat must be removed from ever smaller spaces, see for example, “Silicon CMOS devices beyond scaling”, W. Haensch et al., IBM J. Res. & Dev. 50, 329 (2006); “CMOS downscaling toward the sub-10 nm”, H. Iwai, Solid-State Electronics 48, 497 (2004).

### PROBLEM AND SOLUTION

It is therefore the object of the invention to provide an alternative component for fast switching that has high amplification.

This object is achieved according to the invention by a component according to the main claims and the additional independent claims. A measurement method, in which a component according to the invention is employed, is the subject matter of an additional independent claim. Further advantageous embodiments will be apparent from the dependent claims.

### SUBJECT MATTER OF THE INVENTION

As part of the invention, a triple-gate or multi-gate component was developed. This component comprises at least two tunneling electrodes on a substrate, which are separated by a gap through which electrons can tunnel.

According to the invention, the component comprises means for applying an electric field to the gap, which is such that the path of an electron tunneling between the tunneling electrodes is elongated as a result of the deflection caused by this field.

These characteristics can be implemented in a triple-gate or multi-gate component, comprising at least two tunneling electrodes on a substrate that are separated by a gap through which electrons can tunnel, wherein means for applying an electric field to the gap are provided, this field having lines of electric flux that intersect the shortest path between the tunneling electrodes, without ending at one of these tunneling electrodes. The invention therefore also relates to each component according to the additional independent claim.

It has been found that such an electric field has a particularly high penetration effect on the tunneling probability, by which the electrons can overcome the gap between the tunneling electrodes. The quantum mechanical wave function of the electrons in the gap is exponentially attenuated in the propagation direction. The inventor recognized that, as a result, the tunneling probability exponentially decreases with the length of the path that an electron travels in the gap. It was further recognized that, consequently, elongating the travel even by an atomic diameter causes a change in the tunneling probability, and hence a change in the tunnel current flowing between the tunneling electrodes, by several orders of magnitude.

The above technical teaching according to the main or additional independent claim already suffices for a person skilled in the art to implement the component. From the specific stated problem, the person skilled in the art will already know the geometry of the tunneling electrodes to be produced, the material to use for this purpose, the properties of a material that may be present in the gap, and the voltage to be supplied between the tunneling electrodes. Based on this, the person skilled in the art can determine the shortest path between the tunneling electrodes, and the speed of electrons tunneling through the gap, using ordinary methods. Orienting and dimensioning the electric field in such a way that tunneling electrons undergo a travel elongation as a result of this field in the gap, and yet reach the destination electrode, is a problem that is comparable to the dimensioning of the electric deflecting fields in a cathode ray tube. This problem can therefore likewise be solved with means that are routine to the person skilled in the art. However, it is to the credit of the inventor to even have recognized that the path elongation of tunneling electrons in the gap can be employed as a tool for controlling the tunneling probability, and thus as a mechanism of action for a transistor. According to the prior art, it has not heretofore been possible to influence the tunneling probability in a tunneling arrangement by way of an external electric field.

In a particularly advantageous embodiment of the invention, the substrate is an insulator, such as MgO. However, it is also possible to use SiO₂, Al₂O₃, or Si₃N₄, which, in contrast to MgO, are not hygroscopic. It was recognized that the component having an insulator as the substrate performs the function of a semiconductor component, without requiring the use of a semiconductor. The properties of the substrate are inconsequential, since for the function thereof, only the tunneling of electrons through the gap and the elongation of the path through the gap by means of the electric field are essential. In particular, the substrate does not need to exhibit electron mobility. The higher the electron mobility of the substrate, the greater the quality and speed of conventional semiconductor components.

This opens up the use of materials and production methods that are not compatible with semiconductor manufacturing for producing the component according to the invention. For example, the component does not require any complex tempering steps, such as back-end annealing in hydrogen. It is thus possible to use a wide range of materials.

In a particularly advantageous embodiment of the invention, the substrate comprises a plastic material, which is to say a material composed at least partially of polymers having organic groups. Such a substrate can notably be designed to be pliable. The component is then an element in the field of organic electronics, also referred to as plastic electronics. Because conventional semiconductor electronics technology is dependent on electron mobility in the substrate, and because this mobility is low in organic materials, organic semiconductor components according to the prior art have so far been very slow in their operation. The component according to the invention, for the first time, opens up the path to a transistor having high cut-off frequency on a flexible substrate. At present, the cut-off frequency for OFETs (organic field-effect transistors) is in the range of several 100 kHz. For silicon technology, the cut-off frequency is several 100 GHz. When implementing a tunnel effect transistor as the component according to the invention on a plastic substrate, because electron mobility is eliminated as a limiting factor, the cut-off frequency is in the range of 100 GHz.

In principle, any material is suitable as the electrode material. For ferromagnetic electrodes, spin polarization may be employed to separate the two spinning types during tunneling by way of a magnetic field that is applied. The component is then also a spintronic component. The conductive electrodes, however, may also be inorganic or organic semiconductors. Carbon nanotubes or graphene stand out as particularly stable electrode materials.

In a particularly advantageous embodiment of the invention, the tunneling electrodes have superconductive properties at the intended operating temperature. The tunnel contact formed by the tunneling electrodes thus becomes a Josephson junction. If the critical current I_{C} is not exceeded (logic state “0”), the supercurrent handled by the Cooper pairs does not result in any drop in voltage. The inventor recognized that the element is then in a current-less and hence loss-free state. After applying an electric control field, the Josephson junction is switched to the resistive state (logic state “1”), because the critical current of the gap of the Josephson junction exponentially depends on the path length of the tunneling electrons. The critical current can be lowered so much that it is smaller than thermal fluctuations. As a result, the Josephson junction, in this state, is de facto no longer superconductive (resistive state). The tunnel current is now formed by fermions, such as electrons, and no longer by Cooper pairs, which are bosons and can take on a macroscopic quantum state. The inventor recognized that, in this state as well, only very little power dissipation occurs in the element: If the shortest distance between the tunneling electrodes is greater than approximately 4 nm, the tunnel resistance is very high (in the range of 0.1 GOhm). When a voltage of 0.1 V is applied, the power dissipation therefore is approximately 100 pW.

In a particularly advantageous embodiment of the invention, at least one transistor is configured as the component according to the invention in a processor comprising a plurality of transistors. Preferably, the majority of the transistors of the processor are configured as components according to the invention, and it is particularly preferred when all transistors of the processor are configured as components according to the invention. Advantageously, the tunneling electrodes have superconductive properties at the intended operating temperature in the components according to the invention in the processor. In a processor designed in this way, the advantage of the low power dissipation, and thus waste heat, from a component according to the invention, multiplies as the number of such components increases. Present-day processors, for example, are composed of approximately 800×10⁷ transistors. The processor composed of tunneling transistors according to the invention then only produces a total power dissipation of P=800×10⁷×100 pW=0.8 W when all transistors are in the logic state “1”. Being superconductive, each transistor that is in the logic state “0” must actually be deducted from this total. With the superconductive embodiment, the expected power dissipation is thus approximately two powers of ten less than with current semiconductor processors.

The component according to the invention is a tunnel component, wherein the gap represents the tunnel barrier. The gap is advantageously filled with a vacuum or a gas, such as air. This advantageously reduces the probability that an electron tunneling through the gap is scattered, and hence reduces the electronic noise and the dissipation properties (waste heat) of the component.

The component according to the invention can act as a very fast electronic switch or, depending on the level of the penetration effect of the electric field on the tunneling probability, as a transistor. Such a transistor is considerably faster than heretofore known MOSFET transistors. With this type of transistor, the switching time increases with the square of the length of the gate. At the International Electron Devices Meeting (IEDM) 2002, IBM presented, on a laboratory scale, a MOSFET transistor having a gate length between 4 and 8 nm (Doris et al., “Extreme Scaling with Ultra-thin Silicon Channel MOSFETs”, Electron Devices Meeting 2002, 267-270, ISBN 0-7803-7462-2, doi: 10.1109/IEDM.2002.1175829). Using presently available technology, the component according to the invention can already be produced with gate lengths of 2-3 nm.

A transistor as the component according to the invention has lower power dissipation than a conventional transistor and can also be operated at higher temperatures. The functionality of conventional transistors is based on mutually adjoining semiconductors having different doping. As the temperature rises, the interdiffusion between the differently doped regions, which irreversibly weakens or destroys the transistor, increases exponentially. A transistor that is implemented as the component according to the invention (“variable trajectory tunneling transistor”, VTTT, VT³) is not subject to this limitation.

A transistor that is implemented as the component according to the invention also exhibits a temperature behavior that is substantially only dependent on the stability of the electrode material. Aside from this, only the temperature dependence of the Fermi-Dirac distribution for electrons is decisive for the temperature dependence of the tunneling probability. In the temperatures ranges relevant for the application, this temperature dependence is considerably less than in conventional semiconductor components. In conventional semiconductor electronics, the properties of a semiconductor are decisively dependent on the electron mobility, which is highly, which is to say exponentially, dependent on the temperature.

Finally, a transistor that is implemented as the component according to the invention has a much larger dynamic range than a conventional transistor. The maximum switchable current only depends on the number of electrons that can be provided for tunneling through the gap. This in turn is dependent on the geometry of the tunneling electrodes. In conventional semiconductor components, the maximum switchable current is limited by the number of charge carriers that are mobile in the depletion zone. This advantage of a transistor that is implemented as the component according to the invention is significant wherever conventional transistors go into saturation and the information they are actually intended to amplify is lost. In addition to HiFi amplifiers, these applications notably include measuring amplifiers.

In a particularly advantageous embodiment of the invention, the means comprise at least one control electrode disposed on the substrate. Equipped with such a control electrode, the component is a triple-gate component. The tunneling probability in the gap can be adjusted by way of a voltage that is applied between the control electrode and one of the tunneling electrodes. The control electrode does not have to be located in a plane with the tunneling electrodes. It may also be located beneath or above the plane formed by the tunneling electrodes and the gap, provided it has no electrical contact with either of the tunneling electrodes. It is easier, for example, from a manufacturing technology point of view, to dispose assemblies having different functions, such as tunneling electrodes on the one hand, and the control electrode on the other hand, in different layers on the substrate. This applies in particular when the production of these different assemblies is carried out in different vacuum apparatuses, between which a transfer is only possible by breaking the vacuum.

Advantageously, the distance of the control electrode to any other control electrode or tunneling electrode is greater than the shortest distance between the tunneling electrodes. The tunneling of electrons then takes place exclusively between the tunneling electrodes, and the tunneling probability is controlled by the control electrode almost entirely without current. The finite probability of undesired tunneling from the control electrode decreases exponentially with the distance, however the electric field that is caused by the control electrode and controls the path of the electrons tunneling through the gap only decreases with the square of the distance. Increasing the distance so as to prevent undesired tunneling from the control electrode is thus not associated with disproportionate functionality losses of this control electrode. This effect, which increases gradually with the distance, can already be utilized with relevance for the application if the distance of the control electrode to any other control electrode or tunneling electrode is at least 1.1 times as large as the shortest distance between the tunneling electrodes. Ultimately, the effect is fully pronounced when the distance of the control electrode to any other control electrode or tunneling electrode is at least twice as large as the shortest distance between the tunneling electrodes.

In a particularly advantageous embodiment of the invention, at least two control electrodes are provided, wherein the shortest connecting line between the control electrodes passes through the gap or crosses over or under the gap. The tunneling probability in the gap can then be adjusted by way of a voltage that is applied between the control electrodes.

This embodiment also allows for particularly good measurement of the Hall effect, if a magnetic field is applied to the component. This magnetic field should comprise a component that is advantageously perpendicular both to the tunnel current between the tunneling electrodes and to the shortest connecting line between the control electrodes. For a given tunnel current and magnetic field, the Hall voltage measured between the control electrodes then represents a measure of the mobility of the material present in the gap.

In a particularly advantageous embodiment of the invention, at least one tunnel electrode and/or control electrode is tapered toward the gap. The foremost part of the tip may notably have an apex angle of 30° or less, and preferably 10° or less. The more pointed the taper of a tunneling electrode is, which is to say the smaller the apex angle of the tip thereof is, the more strongly the path of an electron tunneling through the gap up to this tunneling electrode will be elongated by a given electric field. The apex angle of the tip can thus be used to control the penetration effect of the electric field on the tunnel current, and thus the amplification of a component according to the invention acting as a transistor.

Tips or nanogaps comprising two tips that are directed toward each other and separated by a gap of approximately 2-3 nm from each other can be produced, for example, using electron beam lithography, a focused ion beam, or self-organization methods.

Given the information mentioned above, by way of example, with respect to measuring the Hall effect, the invention also relates to a method for measuring the electronic mobility of a sample on the nanoscale using the device according to the invention. In this method, the sample is introduced at least partially into the gap between the tunneling electrodes, and a tunnel current is applied to the gap. In addition, a magnetic field is applied to the gap, which comprises a component perpendicular to the tunnel current. This magnetic field is also advantageously perpendicular to the shortest connecting line between the control electrodes. The separation of the charges transported with the tunnel current is measured, for example, by the presence of a Hall voltage between the control electrodes disposed on the substrate, or between a control electrode and a tunneling electrode.

### SPECIFIC DESCRIPTION

Below, the subject matter of the invention will be described in more detail based on figures, without thereby limiting the subject matter of the invention. In the figures:

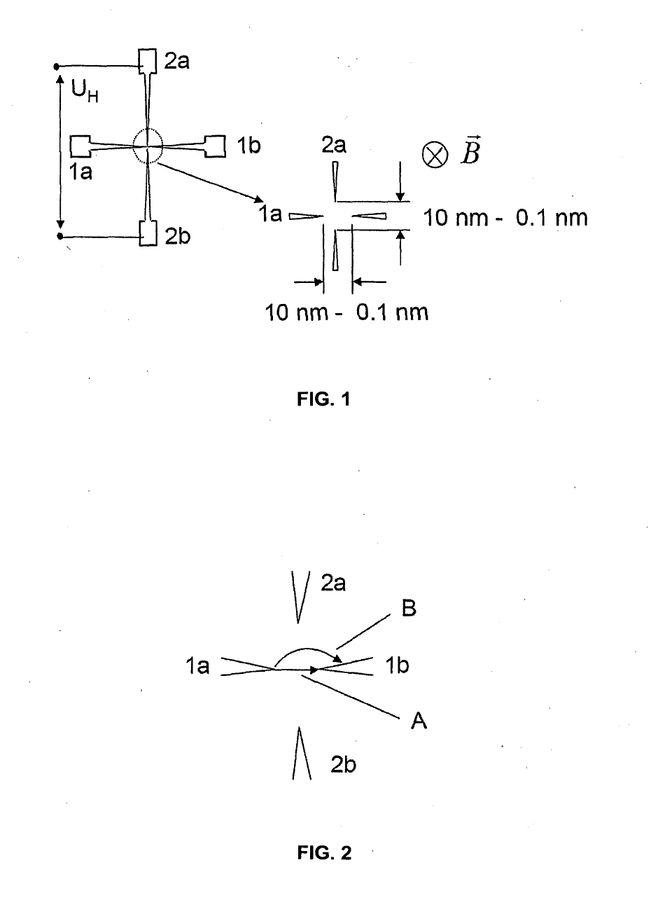

FIG. 1: is a schematic illustration of an embodiment of the component according to the invention.

FIG. 2: shows the effect of the electric field supplied by the control electrodes on the tunnel current through the gap.

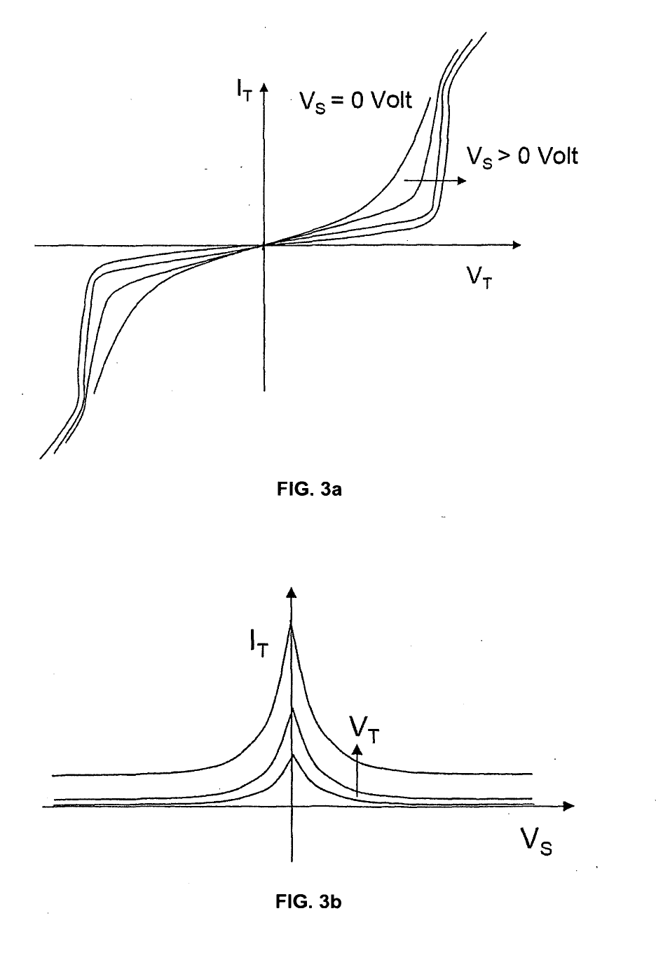

FIG. 3: is a family of output characteristic curves (partial figure a) and input characteristic curves (partial figure b) of the embodiment shown in FIGS. 1 and 2.

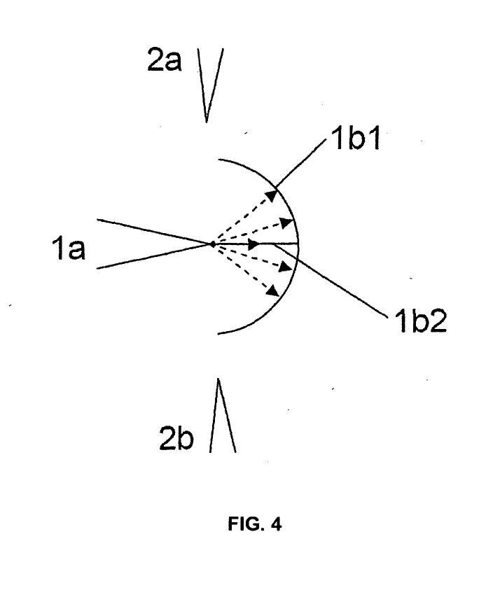

FIG. 4: is an alternative embodiment of the tunnel contacts 1a and 1b in which the component according to the invention is configured as a switch.

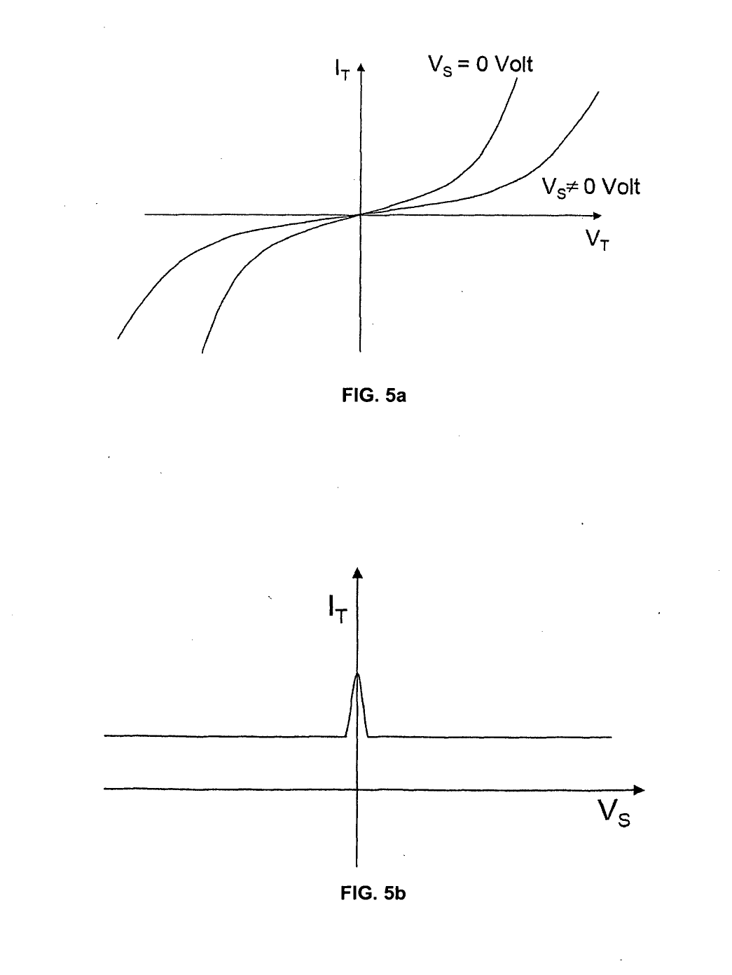

FIG. 5: shows output characteristic curves (partial figure a) and input characteristic curves (partial figure b) of the component according to the invention configured as a switch.

FIG. 1 is a schematic illustration of an embodiment of the component according to the invention, wherein the right part of FIG. 1 is a detailed drawing of the region around the gap. Two tunneling electrodes 1a and 1b configured as tips are directed toward each other, with a gap in the range of 10 nm to 0.1 nm existing therebetween. Two control electrodes 2a and 2b configured as tips are also directed toward each other, with a distance in the range of 10 nm to 0.1 nm therebetween. The component is thus a quadruple-gate component. The shortest connecting line between the control electrodes 2a and 2b passes through the gap. The control electrodes 2a and 2b can be used to apply an electric field to the gap, thereby elongating the path of an electron tunneling through the gap. If, in addition, a magnetic field B is applied to the component, the field having a component perpendicular to the drawing plane, then a Hall voltage U_{H} can be tapped between the control electrodes. This Hall voltage U_{H} is a measure of the electron mobility of the material present in the gap. In this way, it is also possible to carry out the method according to the invention using the component.

FIG. 2 illustrates the principle according to which the electric field supplied by the control electrodes 2a and 2b controls the tunnel current between the tunneling electrodes 1a and 1b. If no voltage is present between the control electrodes 2a, and 2b, the tunneling electrons move through the gap on the shortest path A. However, if a voltage is present, it results in an electric field in the gap. The tunneling electrons are deflected and move through the gap on the longer path B. This reduces the probability of any electrons tunneling between the electrodes 1a and 1b, and hence reduces the tunnel current between these electrodes.

FIG. 3a is qualitative sketch of the family of output characteristic curves of the embodiment of the component according to the invention shown in FIGS. 1 and 2. Plotted is the tunnel current I_{T} over the bias voltage V_{T} supplied between the tunneling electrodes 1a and 1b for different values of the control voltage V_{S} applied between the control electrodes 2a and 2b. In the upper right quadrant of FIG. 3a, the curve shown farthest to the left corresponds to a control voltage V_{S} of 0 volts; curves shown further to the right in the family correspond to higher control voltages V_{S}.

For a control voltage V_{S} of 0 volts, the tunnel current I_{T} will always be the highest, because the electrons tunneling through the gap will always move on the shortest possible path. The higher the amount of the control voltage V_{S}, the longer the path of the electrons through the gap is, and the lower the tunnel current I_{T} for the same bias voltage V_{T} is. Starting at a critical value of V_{T}, the magnitude of which likewise increases as the magnitude of the control voltage V_{S} increases, the intensity of the tunnel current I_{T} rises sharply because the electric field supplied by the bias voltage V_{T} then dominates and drives an increasing number of electrons on the shortest path through the gap, regardless of the field caused by the control voltage V_{S}. For a high V_{T}, the characteristic curve therefore asymptotically approaches the characteristic curve for the case V_{S}=0 volt.

Compared to the characteristic curves of conventional transistors, it is noticeable that, with the transistor according to the invention, a linear behavior is exhibited for the tunnel current I_{T}, which corresponds to the source drain current in a FET, in a smaller range of bias voltage V_{T}, which corresponds to the drain source voltage in a FET. This is due to the circumstance that the quantum mechanical tunnel effect, which forms the basis for the function of the component according to the invention, is a highly non-linear effect. Meanwhile, however, the characteristic curve of the component according to the invention does not exhibit a transition into saturation at higher bias voltages V_{T}, as is commonly found in conventional transistors. As a result, on an overall basis, a considerably wider dynamic range can be used than with conventional transistors, when accepting the non-linearity. No information is “cut off” by the transition into saturation. This is particularly advantageous for HiFi applications and measuring amplifiers.

The characteristic curves, in each case, are polynomials of the third degree, which are approximate solutions of the time-dependent Schrödinger equation.

FIG. 3b shows the family of input characteristic curves corresponding to FIG. 3a. In this illustration, the tunnel current I_{T} is plotted against the control voltage V_{S}, with the bias voltage V_{T} being constant for each of the curves. Higher curves correspond to higher values of the bias voltage V_{T}. The maximum tunnel current I_{T} is obtained in each case for a control voltage V_{S} of 0 volts, because then the electrons tunneling through the gap are not subject to any elongation of the path, and thus the tunneling probability is the highest overall. As the magnitude of the control voltage V_{S} increases, the tunnel current I_{T} drops exponentially, with the gradient of this drop increasing as the bias voltage V_{T} increases. The bias voltage V_{T} thus regulates the amplification of a signal that is supplied via the control voltage V_{S}.

FIG. 4 shows an alternative embodiment of the tunneling electrode 1b, which can be used to design the component according to the invention as a switch. The tunneling electrode 1b comprises a base body 1b1 and a pre-contact 1b2, which is conductively connected to this base body and oriented in the direction of the tunneling electrode 1a. The shape of the base body 1b2 is such that the entire surface thereof oriented toward the tunneling electrode 1a has the same shortest distance to the tunneling electrode 1a. The base body 1b1 can be configured in the shape of a circular arc, for example, and the tunneling electrode 1a can be disposed at the center of the circular arc.

If no control voltage V_{S} is applied, all electrons tunneling between the contacts 1a and 1b will take the shortest path through the gap and impinge on the pre-contact 1b2 (solid arrow). If the amount of the control voltage V_{S} is increased, starting from zero, an increasing number of electrons are deflected, so that they miss the pre-contact 1b2 and impinge on the base body 1b1 (dotted arrows). Independent of the value of the control voltage V_{S}, each electron that misses the pre-contact 1b2 undergoes the same path elongation until it impinges on the base body 1b1. The value of the control voltage thus only decides what portion of tunneling electrons will miss the pre-contact 1b2. Once the amount of the control voltage V_{S} is high enough that all electrons miss the pre-contact 1b2, the tunneling probability, and thus the tunnel current, no longer changes if the control voltage V_{S} is increased further. As a result, essentially two stable states exist for V_{S}=0 volts and for V_{S} ≠0 volt. This is the characteristic of a switch.

FIG. 5a shows the output characteristic lines of an embodiment of the component according to the invention, in which the arrangement of the tunneling electrodes 1a and 1b shown in FIG. 4 is used. The tunnel current I_{T} is plotted over the bias voltage V_{T}. There are exactly two different characteristic curves for V_{S}=0 volt and for V_{S} ≠0 volt. The small voltage V_{S} required to ensure that all tunneling electrons miss the pre-contact 1b2 is not taken into consideration in this illustration. The exact value of this small voltage depends on geometric factors, and on the bias voltage V_{T}, which determines the speed of the tunneling electrons.

FIG. 5b shows the input characteristic curve of the embodiment described in FIG. 5a. The tunnel current I_{T} is plotted over the control voltage V_{S} by way of example of a bias voltage V_{T}. The tunnel current I_{T} is the greatest if no control voltage V_{S} is present, because then all electrons impinge on the pre-contact 1b2. As the amount of the voltage V_{S} increases, an increasing portion of the tunneling electrons miss the pre-contact 1b2 and undergo the path elongation to the base body 1b1. This becomes apparent as a linear drop of the mean tunneling probability, and thus of the tunnel current I_{T}. Once all electrons miss the pre-contact 1b2, which is to say they all impinge on the base body 1b1, the path lengths of the electrons no longer change with a further increases to the magnitude of the voltage V_{S}. The tunnel current I_{T} therefore also remains constant.

1. A triple-gate or multi-gate component, comprising at least two tunneling electrodes on a substrate that are separated by a gap through which electrons can tunnel, said component comprising means for applying an electric field to the gap, which is such that the path of an electron tunneling between the tunneling electrodes is elongated as a result of the deflection caused by this field.

2. A triple-gate or multi-gate component, comprising at least two tunneling electrodes on a substrate that are separated by a gap through which electrons can tunnel, means for applying an electric field to the gap, said field having lines of electric flux that intersect the shortest path between the tunneling electrodes, without ending at one of these tunneling electrodes.

3. A component according to claim 1, wherein the substrate is an insulator.

4. A component according to claim 1, wherein the substrate comprises a plastic.

5. A component according to claim 1, wherein the gap is filled with a vacuum or a gas.

6. A component according to claim 1, wherein the tunneling electrodes have superconductive properties at the intended operating temperature.

7. A component according to claim 1, wherein the means comprise at least one control electrode disposed on the substrate.

8. The component according to claim 7, wherein the shortest distance from the control electrode to any other control electrode or tunneling electrode is greater than the shortest distance between the tunneling electrodes.

9. A component according to claim 7, wherein at least two control electrodes, with the shortest connecting line between the control electrodes passing through the gap or crossing over or under the gap.

10. A component according to claim 1, wherein at least one tunneling and/or control electrode is tapered toward the gap.

11. The component according to claim 10, wherein the foremost part of the tip has an apex angle of 30° or less, and preferably 10° or less.

12. An electronic switch configured as a component according to claim 1.

13. A transistor configured as a component according to claim 1.

14. A processor, comprising a plurality of transistors wherein at least one transistor is according to claim 13.

15. A method for measuring the electronic mobility of a sample on the nanoscale using the component according to claim 1, comprising the following steps:
introducing the sample at least partially into the gap between the tunneling electrodes;
applying a tunnel current to the gap;
applying a magnetic field, which has a component perpendicular to the tunnel current, to the gap; and
measuring the separation of the charges transported by the tunnel current.

16. A component according to claim 2, wherein the substrate is an insulator.

17. A component according to claim 2, wherein the substrate comprises a plastic.

18. A component according to claim 2, wherein the gap is filled with a vacuum or a gas.

19. A component according to claim 2, wherein the tunneling electrodes have superconductive properties at the intended operating temperature.

20. A component according to claim 2, wherein the means comprise at least one control electrode disposed on the substrate.

21. The component according to claim 20, wherein the shortest distance from the control electrode to any other control electrode or tunneling electrode is greater than the shortest distance between the tunneling electrodes.

22. A component according to claim 20, wherein at least two control electrodes, with the shortest connecting line between the control electrodes passing through the gap or crossing over or under the gap.

23. A component according to claim 2, wherein at least one tunneling and/or control electrode is tapered toward the gap.

24. The component according to claim 23, wherein the tip has an apex angle of 30° or less, and preferably 10° or less.

25. An electronic switch according to claim 2.

26. A transistor according to claim 2.

27. A processor, comprising a plurality of transistors wherein at least one transistor is according to claim 26.

28. A method for measuring the electronic mobility of a sample on the nanoscale using the component according to claim 2, comprising the following steps:
introducing the sample at least partially into the gap between the tunneling electrodes;
applying a tunnel current to the gap;
applying a magnetic field, which has a component perpendicular to the tunnel current, to the gap; and
measuring the separation of the charges transported by the tunnel current.
